(19) United States
(12) Patent Application Publication
(10) Pub. No.: US 2013/0206725 A1
(43) Pub. Date: Aug. 15, 2013

(54) CREATION OF OFF-AXIS NULL MAGNETIC FIELD LOCUS FOR IMPROVED UNIFORMITY IN PLASMA DEPOSITION AND ETCHING

(71) Applicants: Karl Leeser, San Jose, CA (US); Ishtak Karim, San Jose, CA (US); Alexandre de Chambrier, Gilroy, CA (US); Liqi Wu, Santa Clara, CA (US); Chunming Zhou, Milpitas, CA (US)

(72) Inventors: Karl Leeser, San Jose, CA (US); Ishtak Karim, San Jose, CA (US); Alexandre de Chambrier, Gilroy, CA (US); Liqi Wu, Santa Clara, CA (US); Chunming Zhou, Milpitas, CA (US)

(21) Appl. No.: 12/725,367

(22) Filed: Mar. 16, 2010

Related U.S. Application Data
(60) Provisional application No. 61/259,082, filed on Nov. 6, 2009.

(51) Int. Cl. C23F 1/00; C23F 1/08; C23C 16/52; C23C 16/00

(52) U.S. Cl. 216/67; 118/723 R; 156/345.51; 427/571

(57) ABSTRACT

Disclosed are methods and associated apparatus for depositing layers of material on a substrate (e.g., a semiconductor substrate) using ionized physical vapor deposition (iPVD). Also disclosed are methods and associated apparatus for plasma etching (e.g., resputtering) layers of material on a semiconductor substrate.

### CROSS REFERENCE TO RELATED APPLICATIONS

This application claims the benefit of US Provisional Patent Application 61/259,082 filed Nov. 6, 2009 by Leeser et al., which Provisional Patent Application is incorporated herein by reference in its entirety.

### BACKGROUND

Disclosed are methods and associated apparatus for depositing layers of material on a semiconductor substrate using ionized physical vapor deposition (iPVD). Also disclosed are methods and associated apparatus for plasma etching (e.g., resputtering) layers of material on a semiconductor substrate.

Ionized physical vapor deposition is used in semiconductor processing for deposition of a variety of layers, such as diffusion barrier layers (e.g., diffusion barriers comprising one or more of Ti, Ta, W, and their nitrides) and seed layers of material (e.g., seed layers including copper and its alloys). Deposition is performed on semiconductor substrates (e.g., 200 mm, 300 mm, or 450 mm circular wafers), which typically include a number of layers of materials (e.g., dielectrics and conductors), residing on a semiconductor. In integrated circuit fabrication, the center-to-edge uniformity of deposition is an important parameter, and it is desirable to control the thicknesses deposited at various radial locations throughout the wafer substrate. More often it is desired to have a uniform deposition profile, in which variation of deposited thickness between center and edge regions of the wafer is minimal. In some cases, however, it may be desirable to controllably increase or decrease deposited thicknesses at a desired radial location on the wafer substrate. In addition to deposition, plasma etching is often used in various contexts in integrated circuit fabrication. As in deposition, control of center-to-edge uniformity is also desirable in plasma etching.

### SUMMARY

Methods and an associated apparatus which allows for uniformity control through creation of radially offset null magnetic field locus are provided. A null magnetic field locus is defined as a spatial region in which all three components of local magnetic field vectors (Bᵣ, B_{z}, and B_{θ}, in cylindrical coordinates) have a magnitude of substantially zero. The apparatus and methods will be primarily illustrated with reference to an iPVD system with the purpose of improving uniformity. However, the provided apparatus and methods are generally applicable for influencing the trajectory of charged species (including plasma, ion beams, and electron beams), in a variety of contexts and applications, beyond iPVD.

In one aspect an apparatus for sputter depositing or sputter etching a layer of material on a semiconductor substrate is disclosed. The apparatus includes the following elements: (a) a process chamber configured for formation of charged species (e.g., plasma, electron beam, ion beam, etc.); (b) a plurality of substantially coaxial sources of magnetic field configured to produce a null magnetic field locus within a region comprising charged species, wherein the null magnetic field locus is radially offset from the central axis defined by the centers of the substantially coaxial sources; and (c) a substrate support for holding the substrate in position during deposition or etching. In general, coaxial sources share a common axis or center and may be offset from one another along the axis. Additionally or alternatively, they may be concentric with respect to one another. In some embodiments, the axis is an axis of radial symmetry in the apparatus of system, e.g., an axis through a center of a sputtering target and/or substrate.

In various embodiments, the apparatus is configured for ionized physical vapor deposition or sputter etching and includes a sputter target. In operation, the target (which is configured as a cathode) may accept a negative electrical bias relative to an anode, which bias may be provided by an appropriate power supply. In certain embodiments, the power supply provides a negative DC bias. The target may be bowl-shaped, as in the case of a hollow cathode magnetron, or planar, for example. In the case of a hollow cathode magnetron, the apparatus may be configured to provide the radially offset null magnetic field locus proximate the target opening or proximate the substrate.

Typically, the apparatus further includes a second plurality of substantially coaxial magnetic field sources (different from the above-described sources for producing the null field) configured for confining a plasma in a first region of the process chamber and for forming a null magnetic field locus on the central axis defined by the centers of the substantially coaxial sources. In these embodiments the central null field locus allows the plasma to escape to a second region of the process chamber, where the substrate resides. Further in these embodiments, the plurality of substantially coaxial magnetic field sources configured to provide the radially offset null field locus is configured to provide said null field locus in a second region of the process chamber. Note that, unless otherwise specified, any of the magnetic field sources described herein may be electromagnets or permanent magnets.

The above-described apparatus is often said to be “configured” to perform some function or attain some result. In general such configuring is accomplished by physically locating or arranging certain elements of the apparatus and/or by including control instructions for performing certain operations in the apparatus (e.g., delivering current of a particular direction and magnitude to one or more electromagnetic coils). To this end, the apparatus will frequently include a controller or controllers having program instructions for delivering current, providing power, moving solenoids, and the like. In some cases, the controller is configured for direct modulation of the position of a null locus during the process of deposition or etching.

In certain embodiments, the null magnetic field locus has a cylindrical shape. As indicated above, null fields having this and similar shapes may be characterized by local magnetic field vectors with radial, axial, and azimuthal components (Bᵣ, B_{z}, and B, respectively) having a magnitude of substantially zero. To this end, the plurality of substantially coaxial sources of magnetic field may be configured to cancel B_{z} and Bᵣ vectors at a locus that is radially offset from the central axis defined by the centers of the substantially coaxial sources. In a specific embodiment, this is accomplished by employing a plurality of substantially coaxial sources of magnetic field including: (i) a first electromagnetic coil configured to substantially cancel the B_{z} vector at a locus that is radially offset from the central axis; and (ii) a pair of additional (sometimes identical) electromagnetic coils configured to cancel the Bᵣ vector at said locus. Note that the pair of additional electromagnetic coils is configured to substantially cancel each other's B_{z} vector at the locus. This may be accomplished by locating the pair of electromagnetic coils substantially equidistant from the locus, and passing opposite currents of substantially equal magnitude through the pair of coils. Further, the null field radius may be controlled by modulation of currents in the plurality of coils.

In certain embodiments, the plurality of substantially coaxial sources of magnetic field include: (i) at least two coaxial electromagnetic coils configured to provide an approximately null Bᵣ vector in the volume spanned by the coils; and (ii) an electromagnetic coil configured to substantially cancel the B_{z} vector at a desired radially offset locus. In certain specific embodiments, the distance between the coils in (i) differs from the mean radius of the coils by no more than about 20% of the mean radius. Further, in these embodiments, the radii of the coils in (i) do not differ from one another by more than about 20% of their mean radius. Note that the coils in (i) may form a single solenoid. Finally, in various embodiments, the electromagnetic coil (ii) has a greater radius than that of each of the coils (i).

In certain other configurations of interest, the plurality of substantially coaxial sources of magnetic field includes first and second concentric electromagnetic coils in one plane configured to provide a null Bᵣ vector in that plane. Further, the coils are configured to accept currents of such magnitudes as to cancel B_{z} vector at a defined radially offset locus on said plane.

In another aspect, methods are disclosed for sputter depositing or sputter etching material on a semiconductor substrate in an apparatus configured for plasma deposition or etching. Such methods may be characterized by the following operations: (a) receiving a substrate in the apparatus, wherein the apparatus comprises a plurality of coaxial magnetic field sources configured for formation of null magnetic field locus in a plasma region; (b) generating a plasma; (c) forming a null magnetic field locus within the plasma region, wherein said null magnetic field locus is radially offset from the central axis defined by the centers of the coaxial sources; and (d) sputter depositing or sputter etching material on the semiconductor substrate using the plasma, generated in (b). The method may include various other operations as necessary to achieve the above-described functions of the apparatus. These operations may include controlling the physical locations and/or sizes (e.g., radii) of the coaxial magnetic field sources and/or controlling the magnetic field strength emanating from the sources by, e.g., controlling current to those sources.

In yet another aspect, methods are disclosed for influencing the trajectory of charged species propagating through a system using a null magnetic field structure. Such methods may be characterized by the following operations: (a) providing a plurality of charged species moving in a magnetic field; and (b) providing a null magnetic field locus in an otherwise non-null magnetic field to influence the trajectory of charged species as desired. In some embodiments, the position of the null field locus with respect to a substrate or other work piece is varied over the time it takes to complete an etching process, a deposition process, or other process on the substrate. The method may include various other operations as necessary to achieve the above-described functions of the apparatus.

These and other features and advantages of the invention will be described in further detail below with reference to the associated drawings.

### BRIEF DESCRIPTION OF THE DRAWINGS

FIG. 1A shows the thickness of deposited layer as a function of radial position on the wafer in a system having a null magnetic field locus residing on the central axis above the wafer center.

FIG. 1B is a simplified illustration of an iPVD apparatus having a region of dense plasma (confinement region) and another region of lower density plasma above the wafer.

FIG. 2 shows a system which contains a plurality of substantially coaxial electromagnetic coils.

FIG. 3A presents a perspective view of a generalized cylindrical null magnetic field locus.

FIG. 3B presents a plan view of the null magnetic field locus of FIG. 3A.

FIG. 3C shows graphically the relationship between magnetic field strength and radial position in a typical system having a cylindrical null magnetic field locus.

FIG. 4 illustrates a single electromagnetic coil, in which the current has a counterclockwise direction, and a local magnetic field vector, B, situated at z₁ and r₁ with a z-direction component B_{z} and a radial component Bᵣ.

FIG. 5 illustrates an apparatus including a plurality of substantially coaxial sources of magnetic field which are configured to cancel the B_{z} and Bᵣ vectors at a locus that is radially offset from the central axis defined by the centers of the substantially coaxial sources.

FIG. 6 illustrates a different apparatus, which includes a plurality of substantially coaxial sources of magnetic field which are configured to provide an approximately null Bᵣ vector and to cancel the B_{z} vector at a locus that is radially offset from the central axis defined by the centers of substantially coaxial sources.

FIG. 7 illustrates another configuration, which includes an inner coil that forms a solenoid and an outer coil, which also forms a solenoid.

FIG. 8 illustrates a system that includes an inner coil and an outer coil, which are concentric and are configured to form a null field locus of a desired radius r1, in the plane of the coils.

FIG. 9 shows an HCM apparatus including a target, a plurality of electromagnetic coils configured to form high density confined plasma close to the target, and a system of coils to create a radially offset null magnetic field locus (circular null locus).

FIG. 10 shows an apparatus including both a centrally located null field locus and a radially offset null field locus, where the system for generating a radially offset null field locus resides in the proximity of the wafer, and where the centrally located null field locus resides in the proximity of a target opening.

FIG. 11 depicts a concept of adding coils in the structure of existing electromagnetic coils to form a radially offset null field locus without changing the set points of the existing coils.

FIG. 12 presents a cross-sectional view of an HCM source suitable for creating a radially offset null field locus.

FIGS. 13A and 13B schematically depict electromagnetic coil and permanent magnet examples, respectively, of magnetic field sources suitable for use with the present invention.

FIG. 14 depicts a non-axisymmetric radially offset null field locus generated in accordance with certain embodiments.

### DETAILED DESCRIPTION OF AN EMBODIMENT

In ionized physical vapor deposition, a plasma is created in a vacuum process chamber containing an inert gas, such as helium, neon, argon, xenon or krypton. A target, which is typically made of a material that needs to be deposited (e.g., a metal, such as copper, tantalum, titanium, or a metal alloy), resides in the process chamber and is biased negatively typically with a DC bias forming a cathode of an iPVD apparatus. The positive inert gas ions formed in a plasma strike the negatively biased target causing sputtering of material from the target onto a substrate which is residing on the pedestal below the target, and which can optionally or additionally be RF-biased. The plasma in the chamber typically contains positively-charged inert gas ions and positively-charged metal ions which were sputtered from the target and ionized in a plasma, along with neutral metal and inert gas atoms. The ionization fraction of metal can vary depending on plasma conditions. The plasma in the process chamber, in some embodiments, can be magnetically confined to form a higher density plasma region (typically in the proximity of the target), and a lower-density plasma region (typically in the proximity of the substrate). In other cases, no distinct regions are formed, but the plasma is shaped, as desired, using magnetic field.

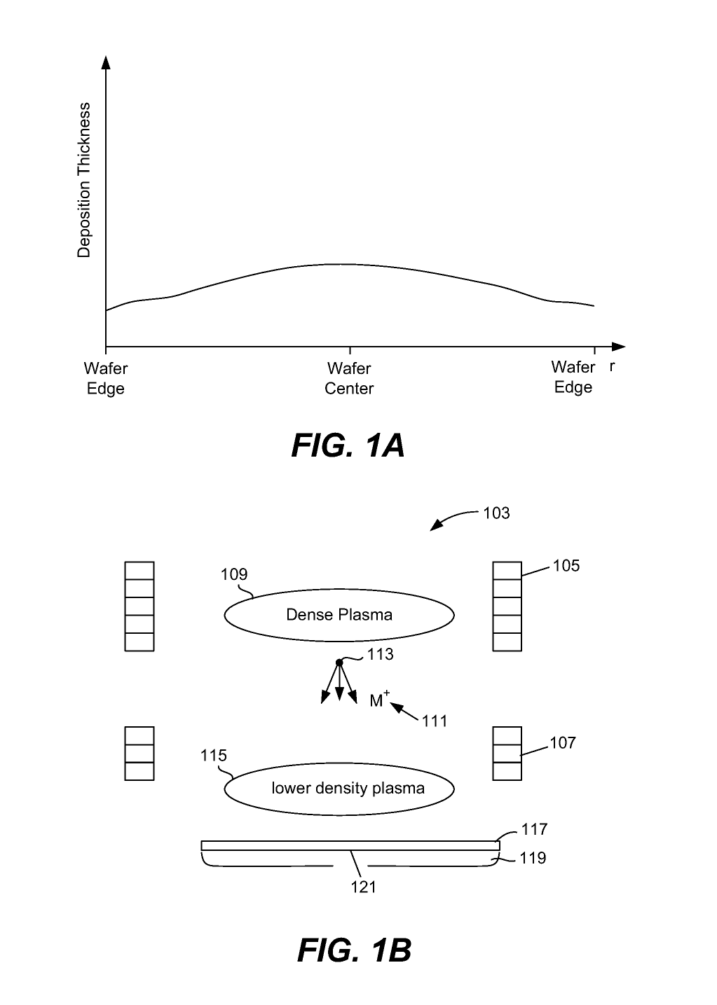

The uniformity of material deposition in such plasma PVD systems greatly depends on variation of the magnetic field strength within the chamber. A strong magnetic field tends to confine the plasma within a region defined by magnetic field lines, while a relatively weaker magnetic field and null magnetic field allows the ions in a plasma to move more freely and escape the confinement. For example, if a null magnetic field locus resides directly above the center of a wafer substrate on the central axis, between the target and the substrate, the metal ions will escape from the plasma in the target region primarily through the central null magnetic field locus and adjacent low-field region, causing center-thick deposition profile as depicted below in FIG. 1A.

Null points in a magnetic field are those points where the total magnetic field completely or substantially vanishes. In accordance with various embodiments disclosed herein a null magnetic field has magnitude below a critical value (B_{crit}), which in one example is about 0.1 Gauss. As explained more fully below, in a system of coaxial (and optionally concentric) EM coils placed along the system axis, null points can be created by driving the current in one or more coils in the opposite direction with respect to that in other coils.

FIG. 1A shows the thickness of deposited layer as a function of radial position on the wafer in a system having a null magnetic field locus residing directly above the wafer center.

FIG. 1B is a simplified illustration of an iPVD apparatus 103 having a region of dense plasma 109 (confinement region) above a wafer 117 and pedestal 119, confined by a plurality of substantially coaxial electromagnetic coils 105, and a plurality of substantially coaxial downstream electromagnetic coils 107 disposed closer to the wafer substrate 117, where the coils 105 and 107 are configured such that a null magnetic field locus 113 exists on a central axis above the wafer center 121. A plasma 115 of lower density than plasma 109 exists between wafer 117 and the null locus. In some embodiments such as that depicted in FIG. 1B, the magnetic topology in the target region is distinctively different from that in the lower density plasma region, and the two regions are separated by an abstract surface referred to as a “separatrix.” The separatrix typically includes the null field locus.

In the configuration of FIG. 1B, ionized species 111 will escape the dense plasma region through the null magnetic field locus 113 at the center. Because the dense plasma region 109 contains ionized metal species, their escape through the center will lead to a center-thick deposition profile as shown in FIG. 1A.

An analogous effect on uniformity is also observed in plasma etching (e.g., resputtering), in which plasma is used to etch a layer of material on a substrate. For example when positive inert gas ions are used for etching, the positive ions are formed in a plasma, and have sufficient energy to strike material on a substrate such that the material is removed (etched) or redistributed. Similarly to the deposition situation, if a null magnetic field locus resides directly above the center of a wafer substrate on the central axis, between the target and the substrate, the inert gas ions will escape from the plasma in the target region primarily through the central null magnetic field locus, causing an increase in the etching rate in the center of the wafer substrate relative to the edges. Accordingly, a center-thin profile would be formed in this case.

The invention in various embodiments provides ways to modulate deposition and etching uniformity, e.g., to deposit substantially uniform layers of material, and to etch material in a substantially uniform manner, by introducing null magnetic field loci, that are radially offset relative to the central axis, which is typically defined by the centers of substantially coaxial magnetic field sources, and which are also typically coaxially disposed with respect to the wafer substrate during deposition or etching. When null magnetic field locus is radially offset, the plasma is capable of escaping from a higher confinement region at a desired radial position thereby allowing control over a deposition or etching profile. However, as mentioned above, the provided methods and apparatus are not limited to uniformity improvement, and can be used to shape and influence trajectories of charged particles for a variety of applications.

Note that the coaxial and/or concentric sources of magnetic field are frequently exemplified herein as “coils.” However, the invention is not limited to coils and those of skill in the art will understand that in many circumstances the coils described herein may be replaced with permanent magnets or any magnetic field source.

In one aspect, a method of sputter depositing or sputter etching material on a semiconductor substrate in an apparatus configured for plasma deposition or etching is provided, where the method includes the following operations: (a) providing a substrate into the apparatus, wherein the apparatus comprises a plurality of substantially coaxial (optionally concentric) magnetic field sources configured for formation of null magnetic field locus in a plasma region; (b) generating a plasma; (c) forming a null magnetic field locus within the plasma region, wherein said null magnetic field locus is radially offset from the central axis defined by the centers of the substantially coaxial sources; (d) sputter depositing or sputter etching material on the semiconductor substrate using the plasma, generated in (b).

In another aspect an apparatus for sputter depositing or sputter etching a layer of material on a semiconductor substrate is provided. The apparatus includes (a) a process chamber configured for formation of charged species (e.g., plasma, electron beam, ion beam, etc.); (b) a plurality of substantially coaxial sources of magnetic field configured to provide a null magnetic field locus within a region comprising charged species, wherein the null magnetic field locus is radially offset from the central axis defined by the centers of the substantially coaxial sources; and (c) a substrate support for holding the substrate in position during deposition or etching.

The radially offset null magnetic field locus can be formed in a variety of types of apparatuses, including PVD apparatus with a planar target, and apparatus having a three-dimensional target, such as an apparatus comprising hollow cathode magnetron. The desired null-field effect can be achieved using coaxial electromagnetic coils (including solenoids), as well as using appropriate arrangements of permanent magnets, and combinations of electromagnetic coils and permanent magnets, as will be understood by one of skill in the art. For the purposes of illustration, and not by way of limitation, the PVD apparatus comprising hollow cathode magnetron comprising a plurality of coaxial electromagnetic coils will be used as an example.

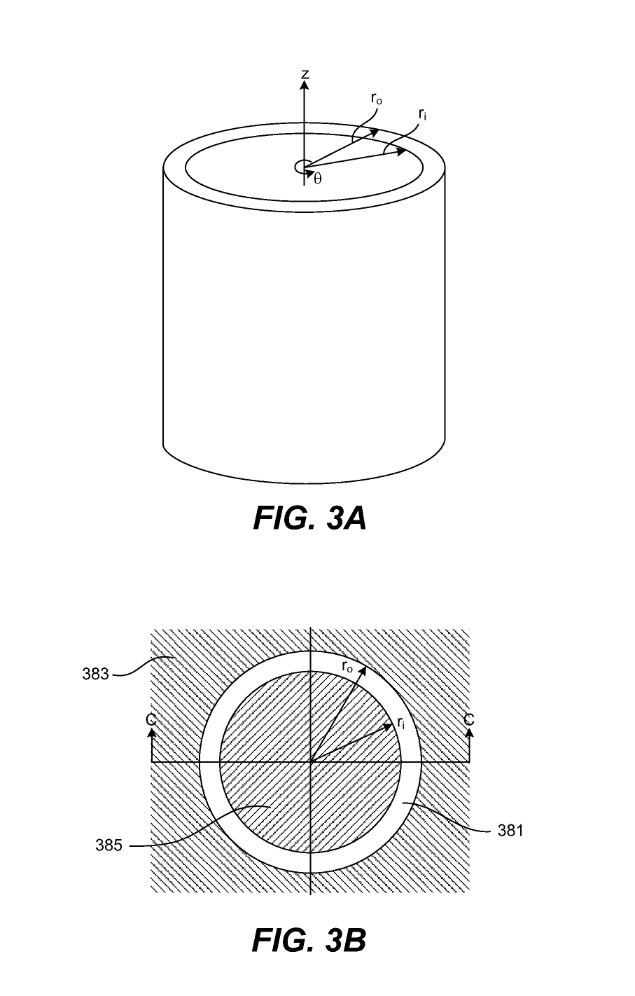

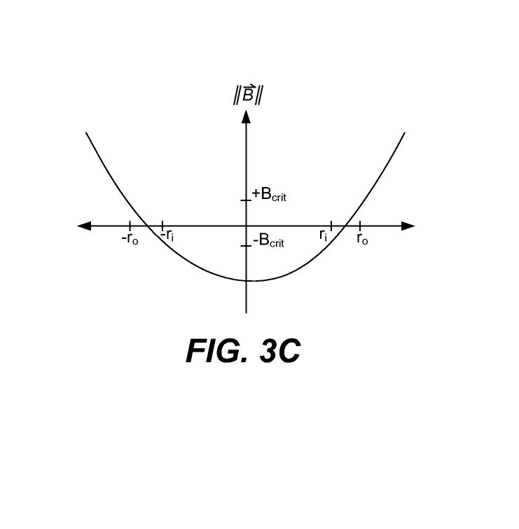

The radially offset null magnetic field locus can have a variety of shapes. In some embodiments the null magnetic field locus has a generally cylindrical shape. In such embodiments the magnetic field has a magnitude of B_{critical} or lower in an annular region 303 defined by an inner radius rᵢ, an outer radius r₀, and a length in the axial or z-direction. Outside of this annular null region, the magnetic field strength is non-zero and greater than B_{critical}. The general shape of such null field locus is illustrated in FIG. 3A. In certain embodiments, the cylindrical null locus forms a thin sheath or shell in which the value of rᵢ approaches that of r₀. In other embodiments, the cylindrical null exists as a “solid” region in which the value of rᵢ is 0. In other words, the locus of null magnetic field extends to the central axis of the cylindrical region. Further, the cylindrical null may have a circular shape in which the length of the region in z-direction approaches zero. Of course, the invention encompasses each of these examples and all intermediate cases.

The cylindrical null field locus is further illustrated in a plan view of FIG. 3B. Within ring-shaped region 381, the magnetic field strength is below B_{critical} (i.e., it is characterized as null). In a region 383 located outside the null ring 381, the magnitude of the magnetic field is greater than B_{critical} (i.e., it is characterized as non-null) and it gradually increases. In a region 385 located inside the null ring, the magnitude of the magnetic field is also greater than B_{critical} and gradually increases. Typically, however, the signs of the magnetic field are opposite in regions 383 and 385.

This is further illustrated in FIG. 3C which shows magnetic field as a function of radial position (in a cross section along the central axis of a symmetric field). Note that the cylindrical null field locus is bounded magnetically by +B_{crit} and −B_{crit} and spatially by rᵢ and r₀.

The radius of the null magnetic field locus (cylindrical or circular), can be modulated as desired. In some embodiments, the radius of the magnetic field locus is increased or decreased, as desired, in the course of deposition or etching. This may be appropriate to facilitate uniform deposition or etching over the work surface of a work piece. In other embodiments, the radius may be adjusted between individual deposition or etching processes. Further, the axial position of the null magnetic field locus (e.g., height above the wafer), can be modulated as desired. In some embodiments, the locus is moved closer to or farther from the wafer, as desired, in the course of deposition or etching. In other embodiments, the axial position is adjusted between individual deposition or etching processes.

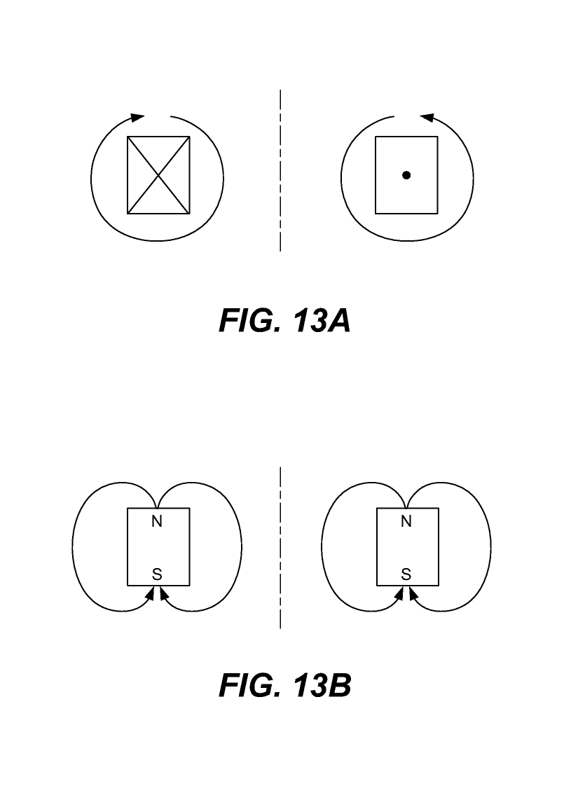

Several configurations of magnetic field sources can be used to radially offset the null magnetic field region. Certain examples of these various embodiments are set forth below. For illustration purposes, these configurations will be shown using magnetic coil configurations. It is, however, understood that permanent magnets and combinations of permanent magnets and electromagnetic coils can be appropriately configured to achieve desired result as is further discussed in the context of FIG. 13B.

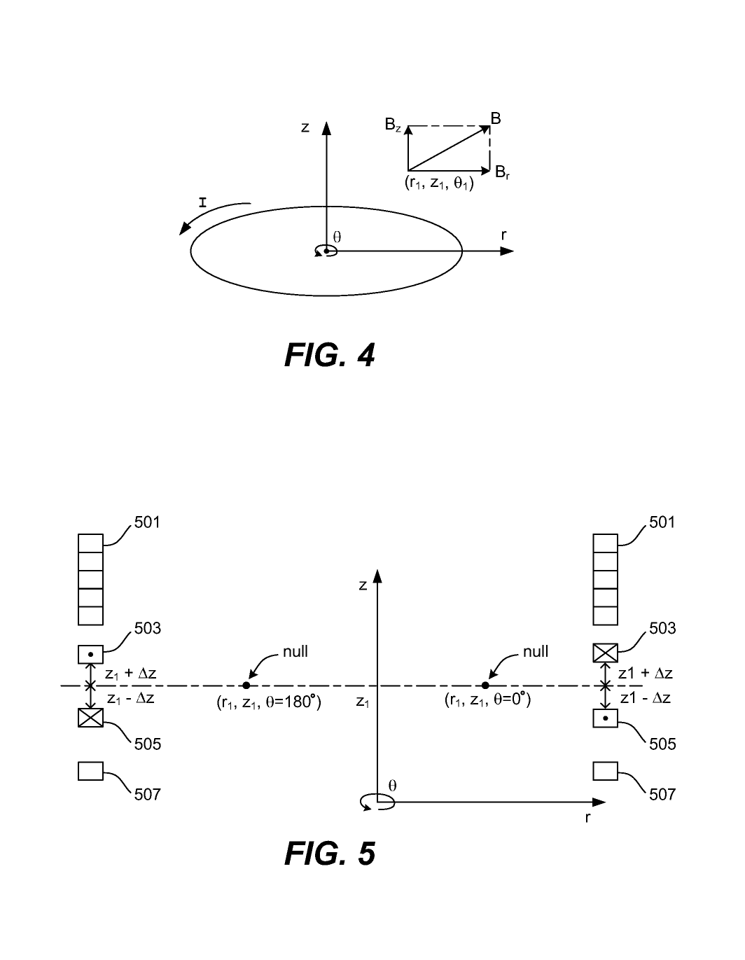

FIG. 4 illustrates a single electromagnetic coil, in which the current has a counterclockwise direction. A z-axis passes through the center of the coil and is perpendicular to the plane of the coil. An r-axis (defining radial position) is perpendicular to the z-axis. A magnetic field is created when current flows through this coil, and an arbitrary location having coordinates (r₁, z₁, θ) will have a B vector with Bᵣ and B_{z} components as shown. If the location is on the z-axis, the Bᵣ component is zero, and only B_{z} component exists.

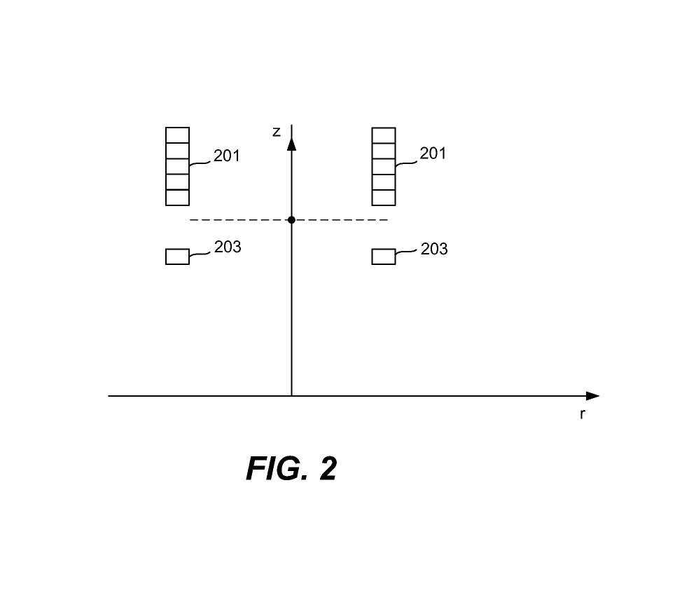

Creation of a central null field locus is illustrated in FIG. 2, which shows a system which contains a plurality of substantially coaxial electromagnetic coils 201. These coils generate a magnetic field having a specific magnitude and direction at various locations. As mentioned above, the B vector has a zero Bᵣ component on the z-axis, therefore only the B_{z} component exists. The magnitude and direction of this field can be calculated using software calculation or modeling packages, such as MAXWELL™ available from Ansoft Corporation of Pittsburgh, Pa., using known parameters for coils 201 (magnitudes and directions of currents in coils 201, number of coil turns, their positions, etc.). In order to create a null magnetic field locus at a desired location on the z-axis, a coil 203 is used, which is configured to produce magnetic field of equal magnitude and of opposite direction at the desired location. The magnitude of required current to be applied through coil 203 is calculated as a function of the desired null height.

Different methods of creating radially offset null magnetic field loci are illustrated in FIGS. 5-8.

In one of the embodiments, the apparatus includes a plurality of substantially coaxial sources of magnetic field which are configured to cancel the B_{z} and Bᵣ vectors at a locus that is radially offset from the central axis defined by the centers of the substantially coaxial sources, wherein the plurality of substantially coaxial sources of magnetic field comprise: (i) a first electromagnetic coil configured to substantially cancel the B_{z} vector at a locus that is radially offset from the central axis; and (ii) a pair of electromagnetic coils configured to substantially cancel the Bᵣ vector at said locus, wherein the pair of electromagnetic coils are configured to cancel each other's B_{z} vector at said locus. An example configuration in accordance with this embodiment is illustrated by FIG. 5.

The system includes a plurality of electromagnetic coils 501 (e.g., coils confining a plasma) and a coil 507, which is configured to cancel the B_{z} vector at a desired location (r₁, z₁), which is radially offset from the z-axis. The system further includes a pair of identical coils 503 and 505, which are configured to substantially cancel the Bᵣ vector at that location, while substantially canceling each other's B_{z} contribution. In order to substantially cancel each other's B_{z} contribution, the coils are substantially equidistant from the desired locus, e.g., coil 503 is above the locus at position z₁+Δz, while coil 507 is below the locus at a position of z₁−Δz. The coils are configured to accept opposing currents of the same magnitude, thereby resulting in local cancellation of the B_{z} component. These coils are configured to cancel the Bᵣ component created by other coils of the system at the desired locus by accepting the current of selected magnitude, which can be calculated using modern calculation software, as understood by those of skill in the art. It is noted that location of coil 507 can be varied and it may reside below, between, or above coils 505 and 503 (or the desired locus). Accordingly by judiciously placing electromagnetic coils and selecting appropriate currents, a null magnetic field locus having a circular shape having radius r₁ and residing at axial position z₁ is created. Notably, the radius of the locus and its axial position can be modulated by modulating current magnitudes and electromagnetic coil locations. For example, in some embodiments, the radius of the locus is modified by adjusting the magnitude of currents supplied to the pair of coils 503 and 505 and coil 507.

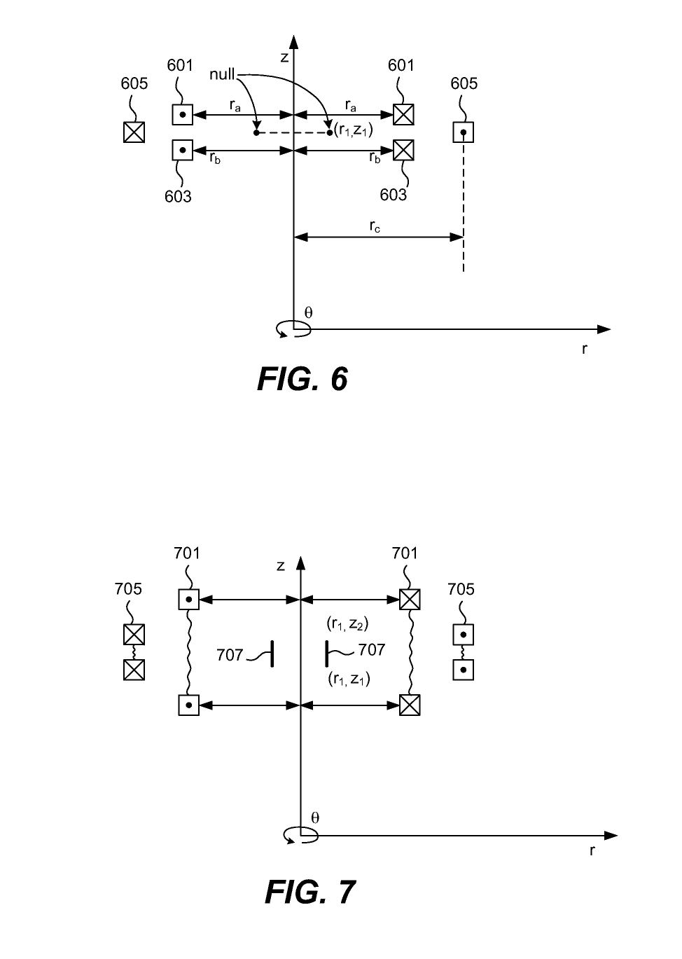

In another embodiment, a different configuration is used to create a null magnetic field locus. In this embodiment, the apparatus includes a plurality of substantially coaxial sources of magnetic field which are configured to provide an approximately null Bᵣ vector and to cancel the B_{z} vector at a locus that is radially offset from the central axis defined by the centers of substantially coaxial sources, wherein the substantially coaxial sources of magnetic field comprise: (i) at least two substantially coaxial coils configured to provide an approximately null Bᵣ vector in the volume spanned by these coils; and (ii) an electromagnetic coil configured to cancel the B_{z} vector at a desired radially offset locus. An example of such configuration is shown in FIG. 6.

The system includes two coils 601 and 603 in close proximity to each other, having currents of relatively similar magnitude running in one direction. Generally, more than two of such coils may be used. Coils 601 and 603 have radii rₐ and r_{b} which are equal in this illustration, but generally may differ. Preferably, the distance between the coils d differs from the mean radius of the coils 601 and 603 by no more than 20% of the mean radius, and where the radii of the coils 601 and 603 do not differ by more than 20% of the mean radius. In some embodiments, coils 601 and 603 are connected to form a solenoid. Because of such arrangement, the Bᵣ component in the volume spanned by said coils is approximately zero. Accordingly at the desired radially offset location (r₁, z₁) within said volume, only the B_{z} vector needs to be cancelled. This is accomplished by using a coil 605 which accepts a current of an opposite direction (from the direction in coils 601 and 603), and of pre-calculated magnitude that is sufficient to cancel the B_{z} vector at a desired location (r₁, z₁). In some embodiments, the radius of coil 605 is larger than the radii of each of coils 601 and 603. In the illustrated configuration, a circular null field locus having radius r1 is created. The radius of this locus can be modified, for example by modulating currents in coil 605 and/or coils 601 and 603 in a pre-calculated manner. Furthermore, the axial location of null field locus can be modulated within the volume spanned by the coils 601 and 603 (or other coils if more is used), by sliding coil 605 along the z-axis.

FIG. 7 illustrates another embodiment, in which the configuration includes an inner coil 701 which forms a solenoid and an outer coil 705, which also forms a solenoid (in other embodiments only one of the coils is a solenoid, e.g., coil 705 is a solenoid, while coils 701 are separate coils configured as in FIG. 6). The Bᵣ vector is approximately zero in the volume spanned by the solenoid 701. The solenoid 705 accepts a current of opposite direction from 701, and of pre-calculated magnitude to cancel the B_{z} vector at a desired radius. A cylindrical null field locus 707 is formed as a result. Similarly, the radius of cylindrical locus can be modulated by modulating the current magnitudes in coils 701 and/or 705. In the case where solenoids 701 and 705 are substantially long (along the direction of the system axis, the z-direction), the cylindrical null will become the volumetric space defined by the intersection of the volumes spanned by solenoid 701 and solenoid 705 (i.e. the null locus becomes a cylindrical solid from a cylindrical shell).

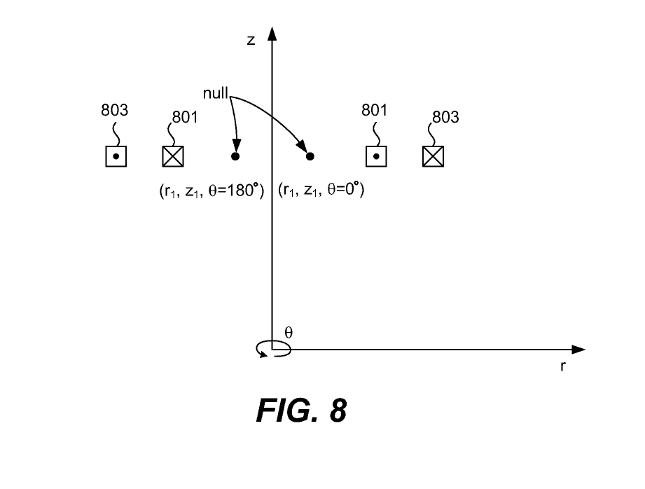

In yet another embodiment, a configuration includes two concentric coils in one plane, which is used to form a radially offset null locus in that plane. This is illustrated in FIG. 8, where the system includes an inner coil 801 and an outer coil 803, which are concentric and are configured to form a null field locus of a desired radius r1, in the plane of coils 801 and 803. This is done by running pre-calculated currents through coils 801 and 803, since the Bᵣ component is equal to zero in the plane, and only the B_{z} component needs to be canceled. The radius of the circular null field locus can be modulated by modulating the ratio of currents running in the coils.

Apparatus

While various embodiments of the present invention can be practiced in many different types of apparatus, a hollow cathode magnetron (HCM) will now be briefly described. A hollow cathode magnetron is a plasma source with a bowl shaped or otherwise reentrant geometry cathode. The present invention is not limited to a specific bowl-shaped geometry of an HCM source and can be used in conjunction with reentrant geometry of a plurality of shapes. In addition, when used for iPVD, the target cathode need not create an HCM; instead a planar target may be employed. More generally, any apparatus (with or without a target), where the trajectory of charged particles needs to be influenced, shaped, or directed can benefit from the configurations described herein.

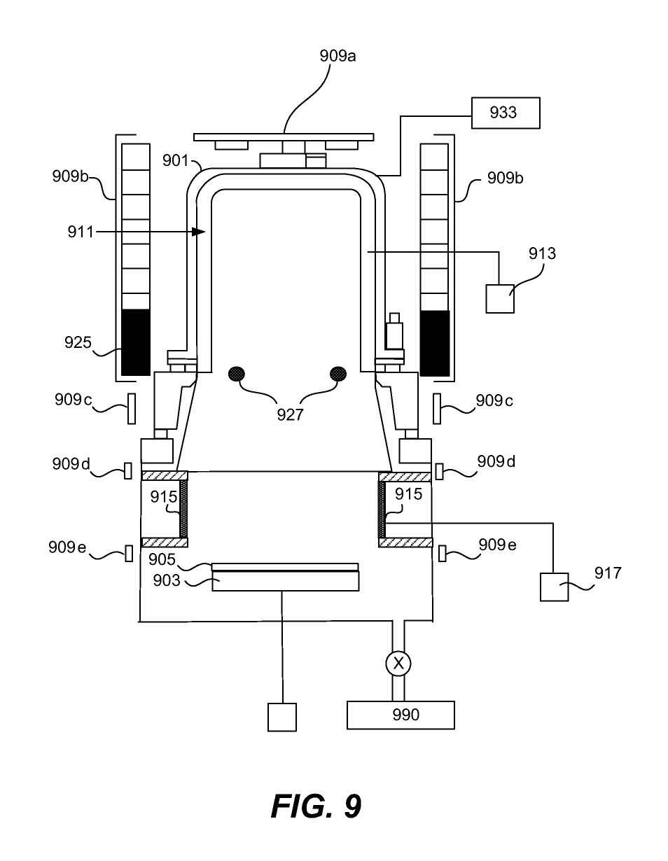

In general, the radially offset null field locus can be created at a variety of locations in the plasma chamber. Further, in some embodiments, both central null field locus and radially offset null field locus are created. In some embodiments, in addition to the coils configured to create radially offset null field locus, the apparatus comprises a second plurality of substantially coaxial magnetic field sources configured for confining a plasma in a first region of the process chamber and wherein the radially offset null magnetic field locus allows the plasma to escape from the first region to a second region of the process chamber. This is illustrated in FIG. 9, which shows an HCM apparatus comprising a target 911, a top rotating magnet 909a, and a plurality of electromagnetic coils 909b configured to form high density confined plasma close to the target. The sputter target 911 is electrically connected to the DC target power supply 913 and is operated at a negative DC bias. A pump 990 is positioned to evacuate or partially evacuate the process chamber. The control of pressure in the process chamber can be achieved by using a combination of gas flow rate adjustments and pumping speed adjustments, making use of, for example, a throttle valve or a baffle plate. Typically the pressure ranges between about 0.01 mTorr and about 100 mTorr during wafer processing.

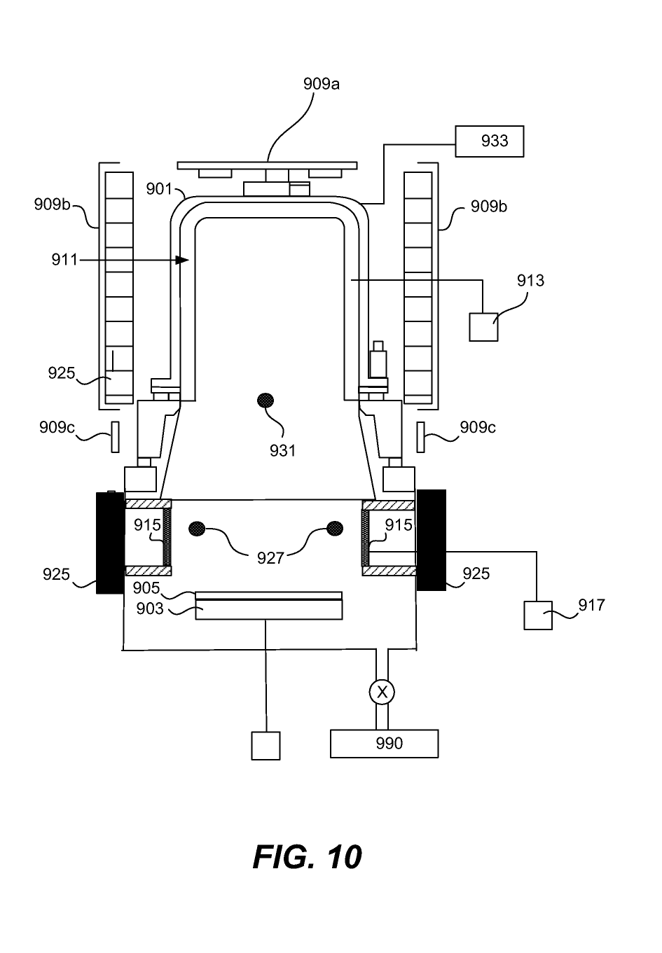

The apparatus further includes a system of coils 925 (as described above) to create a radially offset magnetic field locus 927 (circular locus), through which the plasma can escape from the target region closer to the substrate region. Optionally the apparatus may include a positively biased member 915 (and an associated power supply 917) configured to further assist in attracting plasma to the substrate. Such ion extractor and HCM in general is described in more detail, for example, in commonly owned application Ser. No. 11/807,182 by Anshu Pradhan et al., which is herein incorporated by reference in its entirety, and which can be used as a reference for other components illustrated in FIGS. 9 and 10.

The apparatus further includes a controller 933 comprising program instructions for performing methods described herein (e.g., for providing appropriate currents to electromagnetic coils to create radially offset null field loci and to modulate their radius and position if necessary.

In another embodiment, the apparatus includes both a centrally located null field locus and a radially offset null field locus, as shown in FIG. 10. In the embodiment illustrated in FIG. 10, the system 925 for generating a radially offset null field locus 927 resides in the proximity of the wafer 905 and supporting pedestal 903, whereas the centrally located null field locus 931 resides in the proximity of the target 911 opening.

In certain embodiments, a system controller 933 is employed to control process conditions during deposition and resputter, insert and remove wafers, etc. The controller will typically include one or more memory devices and one or more processors. The processor may include a CPU or computer, analog and/or digital input/output connections, stepper motor controller boards, current and/or voltage controllers, etc.

In certain embodiments, the controller controls all of the activities of the deposition apparatus. The system controller executes system control software including sets of instructions for controlling the currents in individual coils. timing, mixture of gases, chamber pressure, chamber temperature, wafer temperature, target power levels, RF power levels, wafer chuck or susceptor position, and other parameters of a particular process. Other computer programs stored on memory devices associated with the controller may be employed in some embodiments.

Typically there will be a user interface associated with controller 933. The user interface may include a display screen, graphical software displays of the apparatus and/or process conditions, and user input devices such as pointing devices, keyboards, touch screens, microphones, etc.

The computer program code for controlling the deposition and resputtering processes can be written in any conventional computer readable programming language: for example, assembly language, C, C++, Pascal, Fortran or others. Compiled object code or script is executed by the processor to perform the tasks identified in the program.

A further illustration of provided methods and apparatus is described below. A method to create an off-axis magnetic null locus in a magnetron system with substantially coaxial, non-coplanar (in some embodiments, coplanar) electromagnetic (EM) coil sets is provided, in some embodiments. Magnetron systems generally have electromagnets to confine plasma in the target region and to efficiently transfer the sputtered species to the wafer. In some embodiments, the magnetic topology in the target region is distinctively different from that in the transfer region, and the two regions are separated by an abstract surface called the separatrix. The separatrix can contain one or more null points (x-points), where the total magnetic field is zero, through which plasma species can escape the target region to be transferred to the wafer. The embodiments provided herein devise a way to control the radial (direction perpendicular to the system axis) location of the null points, thereby allowing the confined plasma to escape at different radial locations to improve plasma flux uniformity over the wafer.

Ionized PVD in magnetron systems works, in some systems, by confining high density plasma in the target region and then transferring the sputtered species to the wafer. Both the confining and transferring of the ionized species are achieved via applying an appropriate magnetic field. Since the depositing substrate in semi-conductor electronics application is usually a circular wafer, coaxial EM coils are most often used to create the necessary field in order to eliminate azimuthal variation of the system. Confined plasma in the target region is linked to the transfer region through null points on the separatrix. Conventional magnetron systems without strategically placed EM coils lack the ability to create null points at radially offset locations. Since plasma escapes from a null point as a narrow beam, this inevitably results in a deposition profile that has a large radial gradient. The radial non-uniformity can be somewhat controlled by cleverly bending the field lines near the wafer surface, but doing so most likely leads to undesirable in feature coverage.

In one embodiment, magnetic null points are created at arbitrary (although typically prespecified) radial positions in a substantially coaxial, non-coplanar EM coil system. Null points are those points where the total magnetic field substantially vanishes. In a system of coaxial EM coils placed along the system axis, wherein the coil axis coincides with the system axis, null points can be created by driving the current in one or more coils in the opposite direction with respect to that in other coils. This will lead to field cancellation at point(s) on the axis. In such systems, the direction of the B field along the axis is parallel to the axis (B=B_{z}). When one moves away from the z-axis, the total B field will be a vector sum of the axial and radial B field components. Hence in order to form off-axis null points, both B_{z} and Bᵣ should vanish at those points. Since B_{z} and Bᵣ from a given EM coil cannot be independently controlled, satisfying the null condition off axis cannot be done for an arbitrarily placed set of EM coils. For a given set of arbitrarily placed coaxial EM coils, a circular locus of null points with a desired radius can be created by adding three more coaxial EM coils to the system, according to one of the embodiments. The first coil (coil 1) has the function of cancelling the B_{z} field at some desired circle (R₀, Z₀). The exact location of this coil is not critical. The other two coils (coils 2 and 3) must be placed equidistantly above and below (R₀, Z₀); i.e. one at Z₀+ΔZ and the other at Z₀−ΔZ. If equal and opposite currents of correct magnitude are run in these coils, Bᵣ can be cancelled without affecting the already cancelled B_{z}. Therefore, a null circle of radius R₀ can be formed at height Z₀. The necessary current magnitude in coils 2 and 3 is a function of the coil 1 current. Also, the coil 1 current determines the radius of the null circle. By modulating the current in coil 1 and solving for the necessary current magnitude in coils 2 and 3, the null radius can be modulated. Moreover, if either coil 2 or coil 3 is movable in the z-direction, the vertical location of the null circle can be modulated. Thus, in certain embodiments, the apparatus will include a controller programmed to adjust or permit adjustment of the current directions and magnitudes in coils 1-3 and optionally adjust the separation distance of coils 2 and 3 from coil 1 (i.e., adjust the value of Z₀).

In lieu of adding distinct coils, an existing coil on an apparatus that was initially used for purposes other than the creation of a circular null can be used for its creation by applying the sum of the original current and the current required to create the circular null. If the axial location of the said coil is Z₀−ΔZ₁, where Z₀ is the desired axial location of the null, an identical coil can be added at Z₀+ΔZ₁ to form the Bᵣ cancelling pair of coils. Another coil may be added or another existing coil used in a similar fashion for B_{z} cancellation.

A generalization of this principle allows one to use any of the existing coils as one of the three coils necessary to create a circular null by applying a current equal to the sum of the currents needed for the different functions. This allows one to move the circular null to various axial locations by adding appropriate sister coils to existing coils.

The creation of a circular null locus between a target region and a transfer region results in a circular hollow beam emanating from the target region. By modulating the radius of this hollow beam, a uniform deposition profile can be achieved on the wafer. Such modulation may be accomplished via a controller that modulates the currents and/or positions of the relevant coils during the course of a deposition process (e.g., deposition on a single wafer or substrate).

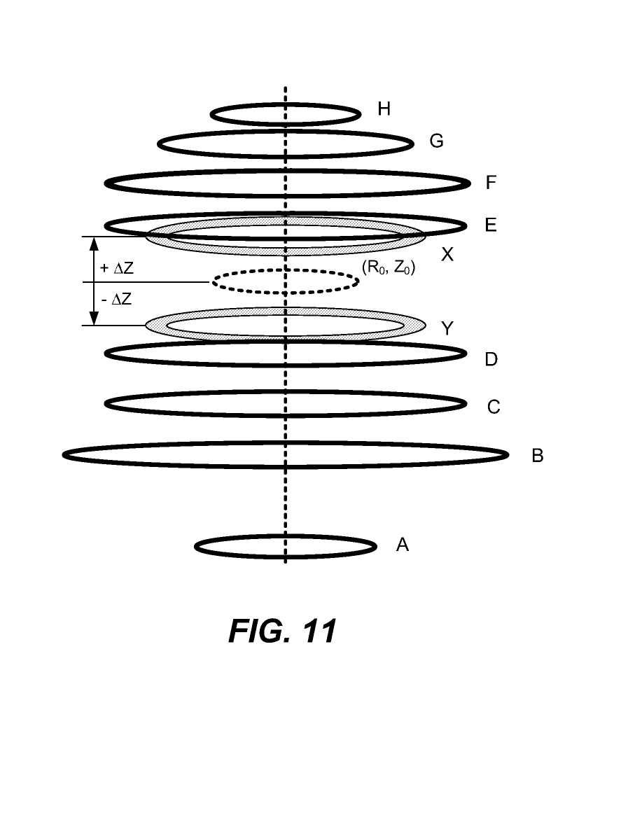

FIG. 11 depicts an example of adding coils in the structure of existing coils to enable the creation of a radially offset null field locus. By adding a pair of identical coils equidistant from the desired null field locus plane, a circular null can be created. Running equal but opposite currents in them applies a desired Bᵣ field at (R₀, Z₀) without perturbing the B_{z} field. In the depicted embodiment, coil D is used to cancel the total B_{z} field and coils X and Y are used to cancel the total Bᵣ field at the locus. The remaining coils in the figure may be present in a conventional device, e.g., an HCM sputtering apparatus.

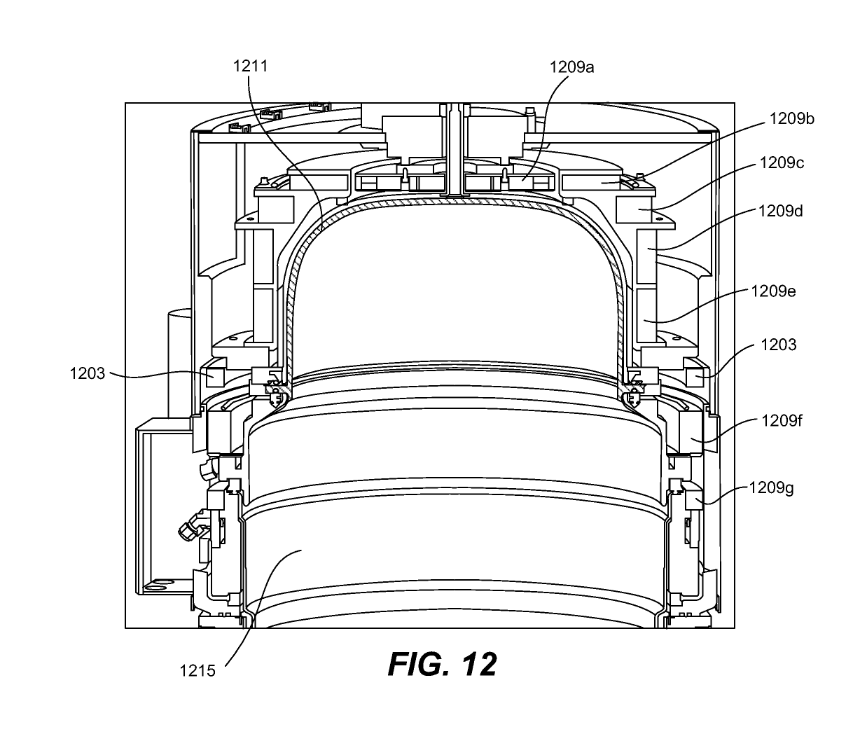

FIG. 12 presents a cross-sectional view of an HCM source suitable for creating a radially offset null field locus. As explained, a hollow cathode magnetron is an apparatus carrying a three-dimensional sputter target. The present invention is not limited to a specific cup-like geometry of an HCM target and can be used in conjunction with any target having a plurality of shapes, including planar.

According to various embodiments, the HCM contains a rotating top magnet 1209a, several annular peripheral electromagnets 1209b-1209g, circumferentially positioned around the process chamber, and a sputter target 1211. The apparatus includes other components such as a shield 1215 designed to protect certain sensitive parts of the apparatus from exposure to plasma. The cathode target 1211 generally has a hollow cup-like shape so that plasma formed in the source can be concentrated within this hollow region. The cathode target 1211 also serves as a sputter target and is, therefore, made of a metal material which is to be deposited onto a substrate. For example, a titanium target is used for deposition of titanium and TiNₓ layers. A tantalum target is used for deposition of tantalum and TaNₓ layers. A copper target is used for copper seed deposition.

During HCM PVD, a strong magnetic field is produced by a combination of permanent magnets 1209a and electromagnets 1209b-1209e around the cathode target region. The electrons emitted from the cathode are confined by the crossing electric and magnetic fields within the hollow portion of the cathode target 1211 to form a region of high plasma density within the hollow cathode. Additional electromagnets 1209f-1209g are arranged downstream from the cathode target and are used to shape the plasma at elevations closer to the wafer pedestal. Discussion of the HCM source and its use in PVD deposition may be found in U.S. Pat. No. 6,179,973 to Lai and U.S. Pat. No. 7,179,351 to Juliano, the disclosures of which are incorporated herein by reference in their entireties.

As described, a radially offset null field region may be formed by appropriate arrangement of coaxial electromagnet coils. In the depicted embodiment, electromagnet 1209f is present in a conventional HCM reactor for shaping the plasma. In an embodiment presented here, it is used as the first coil (coil 1) having the function of cancelling the B_{z} field at a desired circle (R₀, Z₀). Additionally, in the depicted embodiment, electromagnet 1209g is present in a conventional HCM reactor, also for shaping the plasma. In an embodiment presented here, it is used as the second coil (coil 2) located at a position below (R₀, Z₀), i.e. at Z₀−ΔZ. To modify the conventional HCM reactor to allow formation of a null field circle of radius R₀ formed at height Z₀, another coil, electromagnet 1203 (coil 3), is added to the HCM apparatus. Electromagnet 1203 is positioned at an elevation of Z₀+ΔZ. When equal but opposite currents of correct magnitude are run in electromagnets 1209g and 1203, the Bᵣ component can be cancelled without affecting the already cancelled B_{z} component at (R₀, Z₀), thereby forming the null field circle at the said position. In this embodiment, the null height Z₀ is midpoint between electromagnets 1209g and 1203.

Semiconductor processing systems suitable for modification to practice the present invention includes the Inova, Inova xT, and Inova NExT line of PVD tools, available from Novellus Systems, Inc. of San Jose, Calif. Other semiconductor processing systems include Endura, available from Applied Materials, Inc. of Santa Clara, Calif.

While most of the examples above have been provided in the context of coil type magnetic field sources, it was also mentioned that certain embodiments may employ permanent magnets. For illustration, FIG. 13A schematically depicts a coil viewed in cross-section where the right side rectangle represents a portion of the coil where current is flowing out of the plane of the page and the left side rectangle represents a different portion of the coil where current is flowing into the plane of the page. The coil circumferentially surrounds the reactor. FIG. 13B, in contrast, schematically depicts a permanent magnet example of a magnetic field source suitable for use in accordance with certain embodiments. The left and right rectangles in FIG. 13B represent two separate permanent magnets located at the periphery of an apparatus. Typically, multiple additional permanent magnets (not shown) will surround the apparatus and collectively serve the same or a similar role as electromagnetic coils in the embodiments set forth herein. Collectively, a set of permanent magnets circumferentially disposed about an apparatus may be used to assist in producing the radially offset null field locus. Such set of magnets may be used with other magnetic field sources such as other circumferential arrangements of permanent magnets and/or coils.

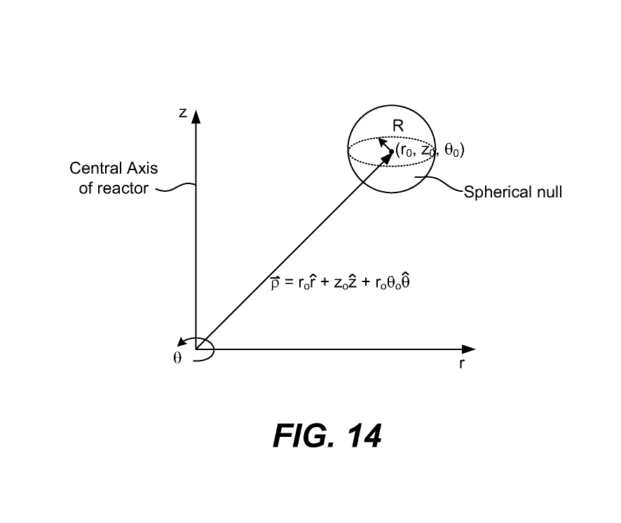

Additionally, the above examples have focused on axisymmetric (with respect to a central axis of an apparatus) null field loci, but the invention is not limited in this manner. In the above examples, the axis of symmetry of the null field loci coincides with that of the associated apparatus. FIG. 14 presents a non-axisymmetric null field example in which a central axis of a processing apparatus does not coincide with a symmetry axis (or more precisely the center point) of a null magnetic field locus. In this example, the null field locus has a spherical shape with a radius R and a center point offset from the origin of a coordinate system of the apparatus by a vector ρ.

Although various details have been omitted for brevity, various design alternatives may be implemented. For example, the null field shapes and locations described above may be optimized for a particular application, as will be understood by those of skill in the art. Accordingly, the present examples are to be considered as illustrative and not restrictive, and the invention is not to be limited to the details given herein but may be modified within the scope of the appended claims.

1. A physical vapor deposition (PVD) apparatus for depositing or etching a layer of material on a substrate, the apparatus comprising:
(a) a process chamber configured for formation of charged species;
(b) a plurality of substantially coaxial sources of magnetic field configured to produce a null magnetic field locus within a region comprising charged species, wherein said null magnetic field locus is radially offset from a central axis defined by the centers of the substantially coaxial sources; and
(c) a substrate support for holding the substrate in position during deposition or etching.

2-24. (canceled)
